(19) United States
(12) Patent Application Publication
(10) Pub. No.: US 2025/0299913 A1
(43) Pub. Date: Sep. 25, 2025

(54) METHOD AND SYSTEM OF OVERLAY MEASUREMENT USING CHARGED-PARTICLE INSPECTION APPARATUS

(71) Applicant: ASML Netherlands B.V., Veldhoven (NL)

(72) Inventor: Antoine Gaston Marie KIERS, Veldhoven (NL)

(73) Assignee: ASML Netherlands B.V., Veldhoven (NL)

(21) Appl. No.: 18/863,313

(22) PCT Filed: Apr. 11, 2023
(86) PCT No.: PCT/EP2023/059399

§ 371 Date: Nov. 5, 2024

(30) Foreign Application Priority Data
May 6, 2022 (EP) 22172200.2

(51) Int. Cl. H01J 37/24; H01J 37/28

(52) U.S. Cl. CPC H01J 37/24; H01J 37/28; H01J 2237/22; H01J 2237/24578

(57) ABSTRACT

Systems and methods of measuring overlay for a sample under a scan performed by a charged-particle beam inspection apparatus include obtaining a first detector signal in response to a first scan of a first target of the sample and a second detector signal in response to a second scan of a second target of the sample; determining a first transformed signal and a second transformed signal by performing a Fourier transform on the first detector signal and the second detector signal; and determining, based on the first transformed signal and the second transformed signal, an overlay value of the sample.

### CROSS-REFERENCE TO RELATED APPLICATIONS

This application claims priority of EP Application Serial No. 22172200.2 which was filed on May 6, 2022 and which is incorporated herein in its entirety by reference.

### FIELD

The description herein relates to the field of image inspection apparatus, and more particularly to overlay measurement using charged-particle inspection apparatuses.

### BACKGROUND

An image inspection apparatus (e.g., a charged-particle beam apparatus or an optical beam apparatus) is able to produce a two-dimensional (2D) image of a wafer substrate by detecting particles (e.g., photons, secondary electrons, backscattered electrons, mirror electrons, or other kinds of electrons) from a surface of a wafer substrate upon impingement by a beam (e.g., a charged-particle beam or an optical beam) generated by a source associated with the inspection apparatus. Various image inspection apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), or defect analysis (e.g., defect review SEM, or say DR-SEM and Focused Ion Beam system, or say FIB).

In semiconductor manufacturing, integrated circuits may be fabricated as one or more stacked layers of materials (e.g., silicon, silicon dioxide, metal, or the like) on a wafer. Each layer of material may include a designed pattern (referred to as a “pattern layer” herein) for forming components (e.g., transistors, contacts, or the like) of the integrated circuits. The fabrication of each layer involves transferring a pattern from a mask onto the wafer surface through a lithography process. The position of each pattern layer relative to its previous pattern layer (referred to as “alignment” herein) may influence characteristics or quality of the manufactured integrated circuits.

Overlay refers to a planar, vectorial shift, displacement, or misalignment of a pattern layer with respect to its neighboring pattern layer. For example, two intra-pattern reference points (e.g., center points) may be selected for two patterns in two neighboring pattern layers, respectively, and the overlay between the two neighboring pattern layers may refer to a planar, vectorial displacement between the two intra-pattern reference points. Large overlay may cause problems or failures of the manufactured integrated circuits. Therefore, high-precision overlay measurement plays an important role in reducing the overlay.

### SUMMARY

Embodiments of the present disclosure provide systems and methods of measuring overlay for a sample under a scan performed by a charged-particle beam inspection apparatus. In some embodiments, a system may include a charged-particle beam inspection apparatus configured to scan a sample, and a controller including circuitry. The controller may be configured to obtain a first detector signal in response to a first scan of a first target of the sample and a second detector signal in response to a second scan of a second target of the sample, determine a first transformed signal and a second transformed signal by performing a Fourier transform on the first detector signal and the second detector signal, and determine, based on the first transformed signal and the second transformed signal, an overlay value of the sample.

In some embodiments, a non-transitory computer-readable medium may store a set of instructions that is executable by at least one processor of an apparatus to cause the apparatus to perform a method. The method may include obtaining a first detector signal in response to a first scan of a first target of the sample and a second detector signal in response to a second scan of a second target of the sample; determining a first transformed signal and a second transformed signal by performing a Fourier transform on the first detector signal and the second detector signal; and determining, based on the first transformed signal and the second transformed signal, an overlay value of the sample.

In some embodiments, a method of measuring overlay for a sample under a scan performed by a charged-particle beam inspection apparatus may include obtaining a first detector signal in response to a first scan of a first target of the sample and a second detector signal in response to a second scan of a second target of the sample; determining a first transformed signal and a second transformed signal by performing a Fourier transform on the first detector signal and the second detector signal; and determining, based on the first transformed signal and the second transformed signal, an overlay value of the sample.

In some embodiments, a system may include a charged-particle beam inspection apparatus configured to scan a sample, and a controller including circuitry. The controller may be configured to obtain a detector signal in response to a scan of a target of the sample, determine a first transformed signal by performing a Fourier transform on the detector signal and a second transformed signal by converting the first transformed signal, and determine an overlay value of the sample based on the first transformed signal, the second transformed signal, a first predetermined amplitude value, and a second predetermined amplitude value.

In some embodiments, a non-transitory computer-readable medium may store a set of instructions that is executable by at least one processor of an apparatus to cause the apparatus to perform a method. The method may include obtaining a detector signal in response to a scan of a target of a sample scanned by a charged-particle beam inspection apparatus, determining a first transformed signal by performing a Fourier transform on the detector signal and a second transformed signal by converting the first transformed signal, and determining an overlay value of the sample based on the first transformed signal, the second transformed signal, a first predetermined amplitude value, and a second predetermined amplitude value.

In some embodiments, a method of measuring overlay for a sample under a scan performed by a charged-particle beam inspection apparatus may include obtaining a detector signal in response to a scan of a target of a sample scanned by a charged-particle beam inspection apparatus, determining a first transformed signal by performing a Fourier transform on the detector signal and a second transformed signal by converting the first transformed signal, and determining an overlay value of the sample based on the first transformed signal, the second transformed signal, a first predetermined amplitude value, and a second predetermined amplitude value.

### BRIEF DESCRIPTION OF THE DRAWINGS

FIG. 1 is a schematic diagram illustrating an example charged-particle beam inspection (CPBI) system, consistent with some embodiments of the present disclosure.

FIG. 2 is a schematic diagram illustrating an example charged-particle beam tool, consistent with some embodiments of the present disclosure that may be a part of the example charged-particle beam inspection system of FIG. 1.

FIG. 3 is a schematic diagram illustrating an example measurement process of a surface structure and a sub-surface structure using a charged-particle beam tool, consistent with some embodiments of the present disclosure.

FIG. 4 is a schematic diagram illustrating examples of a first target and a second target manufactured on a sample, consistent with some embodiments of the present disclosure.

FIG. 5 is a graph illustrating example visualization of a first detector signal and a second detector signal, consistent with some embodiments of the present disclosure.

FIG. 6 is a schematic diagram illustrating an example target manufactured on a sample, consistent with some embodiments of the present disclosure.

FIG. 7 is a schematic diagram illustrating an example arrangement of targets manufactured on a sample, consistent with some embodiments of the present disclosure.

FIG. 8 is a flowchart illustrating an example method of overlay measurement, consistent with some embodiments of the present disclosure.

FIG. 9 is a flowchart illustrating another example method of overlay measurement, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection may be carried out using a scanning charged-particle microscope (“SCPM”). For example, a scanning charged-particle microscope may be a scanning electron microscope (SEM). A scanning charged-particle microscope may be used to image these extremely small structures, in effect, taking a “picture” of the structures of the wafer. The image may be used to determine if the structure was formed properly in the proper location. If the structure is defective, then the process may be adjusted, so the defect is less likely to recur.

The working principle of a scanning charged-particle microscope (e.g., a SEM) is similar to a camera. A camera takes a picture by receiving and recording intensity of light reflected or emitted from people or objects. A scanning charged-particle microscope takes a “picture” by receiving and recording energies or quantities of charged particles (e.g., electrons) reflected or emitted from the structures of the wafer. Typically, the structures are made on a substrate (e.g., a silicon substrate) that is placed on a platform, referred to as a stage, for imaging. Before taking such a “picture,” a charged-particle beam may be projected onto the structures, and when the charged particles are reflected or emitted (“exiting”) from the structures (e.g., from the wafer surface, from the structures underneath the wafer surface, or both), a detector of the scanning charged-particle microscope may receive and record the energies or quantities of those charged particles to generate an inspection image. To take such a “picture,” the charged-particle beam may scan over the wafer (e.g., in a line-by-line or zig-zag manner), and the detector may receive exiting charged particles coming from a region under charged particle-beam projection (referred to as a “beam spot”). The detector may receive and record exiting charged particles from each beam spot one at a time and join the information recorded for all the beam spots to generate the inspection image. Some scanning charged-particle microscopes use a single charged-particle beam (referred to as a “single-beam scanning charged-particle microscope,” such as a single-beam SEM) to take a single “picture” to generate the inspection image, while some scanning charged-particle microscopes use multiple charged-particle beams (referred to as a “multi-beam scanning charged-particle microscope,” such as a multi-beam SEM) to take multiple “sub-pictures” of the wafer in parallel and stitch them together to generate the inspection image. By using multiple charged-particle beams, the SEM may provide more charged-particle beams onto the structures for obtaining these multiple “sub-pictures,” resulting in more charged particles exiting from the structures. Accordingly, the detector may receive more exiting charged particles simultaneously and generate inspection images of the structures of the wafer with higher efficiency and faster speed.

To control quality of the manufactured semiconductor structures, various overlay measurement techniques may be used. Typically, overlay may be measured using optical tools. For example, a broadband light beam may be shed on a surface of a sample. The surface may include a specifically designed and manufactured structure (also referred to as “target” herein). The target may include a first layer (e.g., a top layer) and a second layer (e.g., a bottom layer) below the first pattern layer. An optical scatterometry tool may be used to measure reflection or diffraction of the broadband light reflected by the target. The reflection or diffraction may have various characteristics, such as different wavelengths, polarization, angle-of-incidence, phases, or other optical characteristics, from which unknown properties (e.g., overlay) of the sample may be determined.

By way of example, the overlay of a target may be determined based on a phase difference between diffractions of a first layer (e.g., a top layer) and a second layer (e.g., a layer beneath the first layer), each of the first layer and the second layer including a specific structure (e.g., a grating). The overlay determined using such a target may be referred to as a diffraction-based overlay (“DBO”). To measure a diffraction-based overlay, structures (e.g., gratings) in the first player and the second player may be manufactured with a programmed shift. A programmed shift between two layers herein may refer to a designed (known) planar, vectorial displacement between the two layers. The programmed shift may be used to remove or reduce imperfections in the optical scatterometry measurements.

Several technical challenges exist in the optical based overlay measurement techniques. A first challenge is that signals of the reflection or diffraction become weaker as a pitch of the target (e.g., a pitch of a grating) decreases and as separation between neighboring pattern layers increases. A “pitch” in this disclosure refers to the minimum center-to-center distance between interconnect lines in a manufactured integrated circuit, which may be used as an indicator of an integration level of the integrated circuit. A second challenge is that selecting a wavelength of the broadband light beam for the optical based overlay measurement techniques may be complicated because each wavelength may yield different measurement results. A third challenge is that measurement results of the optical based overlay measurement techniques may be sensitive to subtle tilts of areas between lines of the targets (e.g., lines of the gratings). Those challenges may increase the uncertainties and inaccuracy in the overlay measurements.

Embodiments of the present disclosure may provide methods, apparatuses, and systems for non-optical overlay measurement. In some disclosed embodiments, a scanning charged-particle microscope (e.g., a SEM) may be used for overlay measurements using one or more targets. The scanning charged-particle microscope may inject a charged-particle beam (e.g., an electron beam) onto a surface of the one or more targets, each of which includes a first layer (e.g., a top layer) and a second layer (e.g., below the first layer). Each of the first layer and the second layer may include a similar pattern (e.g., gratings with the same pitch and a programmed shift). The incident charged-particle beam may interact with the pattern in the first layer and the pattern in the second layer to generate secondary electrons and backscattered electrons. The outgoing secondary electrons and backscattered electrons may be detected by a detector to generate signals. By analysis of the signals, an overlay between the first layer and the second layer may be determined. Compared with the optical based overlay measurement techniques, the non-optical overlay measurement may reduce or remove the above-described challenges, and accuracy of the overlay measurement may be greatly improved.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

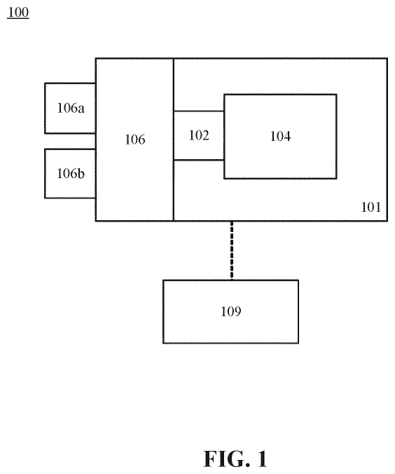

FIG. 1 illustrates an exemplary charged-particle beam inspection (CPBI) system 100 consistent with some embodiments of the present disclosure. CPBI system 100 may be used for imaging. For example, CPBI system 100 may use an electron beam for imaging. As shown in FIG. 1, CPBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer that may execute various controls of CPBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

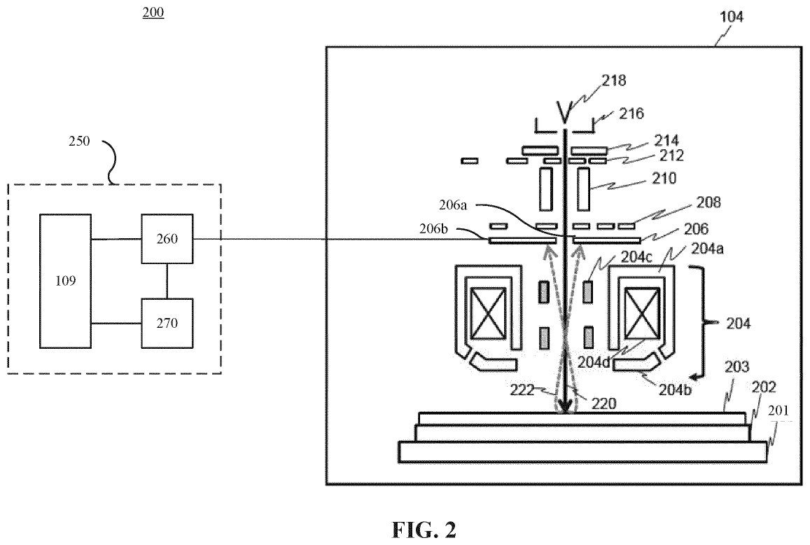

FIG. 2 illustrates an example imaging system 200 according to embodiments of the present disclosure. Beam tool 104 of FIG. 2 may be configured for use in CPBI system 100. Beam tool 104 may be a single beam apparatus or a multi-beam apparatus. As shown in FIG. 2, beam tool 104 includes a motorized sample stage 201, and a wafer holder 202 supported by motorized sample stage 201 to hold a wafer 203 to be inspected. Beam tool 104 further includes an objective lens assembly 204, a charged-particle detector 206 (which includes charged-particle sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Beam tool 104 may additionally include an Energy Dispersive X-ray Spectrometer (EDS) detector (not shown) to characterize the materials on wafer 203.

A primary charged-particle beam 220 (or simply “primary beam 220”), such as an electron beam, is emitted from cathode 218 by applying an acceleration voltage between anode 216 and cathode 218. Primary beam 220 passes through gun aperture 214 and beam limit aperture 212, both of which may determine the size of charged-particle beam entering condenser lens 210, which resides below beam limit aperture 212. Condenser lens 210 focuses primary beam 220 before the beam enters objective aperture 208 to set the size of the charged-particle beam before entering objective lens assembly 204. Deflector 204c deflects primary beam 220 to facilitate beam scanning on the wafer. For example, in a scanning process, deflector 204c may be controlled to deflect primary beam 220 sequentially onto different locations of top surface of wafer 203 at different time points, to provide data for image reconstruction for different parts of wafer 203. Moreover, deflector 204c may also be controlled to deflect primary beam 220 onto different sides of wafer 203 at a particular location, at different time points, to provide data for stereo image reconstruction of the wafer structure at that location. Further, in some embodiments, anode 216 and cathode 218 may generate multiple primary beams 220, and beam tool 104 may include a plurality of deflectors 204c to project the multiple primary beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary beam 220 may be immersed in the magnetic field and may be electrically charged, which, in turn, creates an electric field. The electric field reduces the energy of impinging primary beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary charged-particle beam 222 (or “secondary beam 222”), such as secondary electron beams, may be emitted from the part of wafer 203 upon receiving primary beam 220.

Secondary beam 222 may form a beam spot on sensor surfaces 206a and 206b of charged-particle detector 206. Charged-particle detector 206 may generate a signal (e.g., a voltage, a current, or the like.) that represents an intensity of the beam spot and provide the signal to an image processing system 250. The intensity of secondary beam 222, and the resultant beam spot, may vary according to the external or internal structure of wafer 203. Moreover, as discussed above, primary beam 220 may be projected onto different locations of the top surface of the wafer or different sides of the wafer at a particular location, to generate secondary beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, post-processed images, or other images assisting of the processing. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

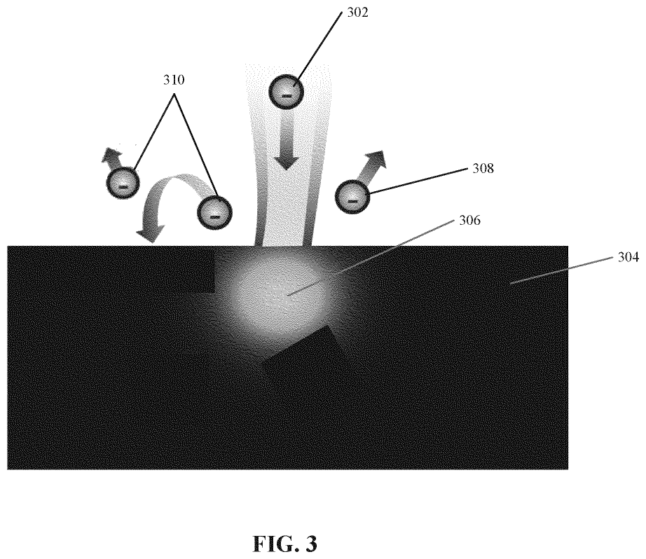

FIG. 3 is a schematic diagram illustrating an example measurement process of a surface structure and a sub-surface structure using a charged-particle beam tool (e.g., a scanning charged-particle microscope), consistent with some embodiments of the present disclosure. A scanning charged-particle microscope (“SCPM”) generates a primary charged-particle beam (e.g., primary charged-particle beam 220 in FIG. 2) for inspection. For example, the primary charged-particle beam may be a primary electron beam. In FIG. 3, electrons of a primary electron beam 302 are projected onto a surface of a sample 304. Sample 304 may be of any materials, such as a non-conductive resist, a silicon dioxide layer, a metallic layer, or any stacked combination of any dielectric or conductive material.

The electrons of primary electron beam 302 may penetrate the surface of sample 304 for a certain depth (e.g., from several nanometers to several micrometers), interacting with particles of sample 304 in interaction volume 306. Some electrons of primary electron beam 302 may elastically interact with (e.g., in a form of elastic scattering or collision) the particles in interaction volume 306 and may be reflected or recoiled out of the surface of sample 304. An elastic interaction conserves the total kinetic energies of the bodies (e.g., electrons of primary electron beam 302 and particles of sample 304) of the interaction, in which no kinetic energy of the interacting bodies convert to other forms of energy (e.g., heat, electromagnetic energy, etc.). Such reflected electrons generated from elastic interaction may be referred to as backscattered electrons (BSEs), such as BSE 308 in FIG. 3. Some electrons of primary electron beam 302 may inelastically interact with (e.g., in a form of inelastic scattering or collision) the particles in interaction volume 306. An inelastic interaction does not conserve the total kinetic energies of the bodies of the interaction, in which some or all of the kinetic energy of the interacting bodies may covert to other forms of energy. For example, through the inelastic interaction, the kinetic energy of some electrons of primary electron beam 302 may cause electron excitation and cause generation of electrons exiting the surface of sample 304, which may be referred to as secondary electrons (SEs), such as SE 310 in FIG. 3. As depicted in FIG. 3, some of SE 310 (e.g., SE's with sufficient energy) may eventually exit the surface of sample 304 and reach a detector (not shown in FIG. 3), and some of SE 310 (e.g., SE's with insufficient energy) may eventually exit and re-enter the surface of sample 304 (e.g., when the surface of sample 304 is positively charged). Yield or emission rates of BSEs and SEs may depend on, for example, the energy of the electrons of primary electron beam 302 and the material under inspection, among other factors. The energy of the electrons of primary electron beam 302 may be imparted in part by its acceleration voltage (e.g., the acceleration voltage between anode 216 and cathode 218 in FIG. 2). The quantity of BSEs and SEs may be more or fewer (or even the same) than the injected electrons of primary electron beam 302.

By way of example, sample 304 may include a first layer (e.g., a resist layer on top of a wafer surface, not illustrated in FIG. 3) and a second layer (e.g., a pattern layer beneath the wafer surface, not illustrated in FIG. 3). Each of the first layer and the second layer may include a designed pattern (e.g., a target), such as lines, slots, corners, edges, holes, or the like. Those features may be at different heights. Primary electron beam 302 may interact with particles in the first layer to generate SE 310, and SE 310 generated at different locations of the target in the first layer may reflect geometric information of the target in the first layer. Primary electron beam 302 may also penetrate the first layer to reach and interact with particles in the second layer to generate BSE 308, and BSE 308 generated at different locations of the target in the second layer may reflect geometric information of the target in the second layer.

Consistent with some embodiments of this disclosure, a computer-implemented method of measuring overlay for a sample under a scan performed by a charged-particle beam inspection apparatus may include obtaining a first detector signal in response to a first scan of a first target of the sample and a second detector signal in response to a second scan of a second target of the sample. The obtaining, as used herein, may refer to accepting, taking in, admitting, gaining, acquiring, retrieving, receiving, reading, accessing, collecting, or any operation for inputting data. In some embodiments, the charged-particle beam inspection apparatus may include a scanning electron microscope. The sample may include a wafer.

By way of example, the charged-particle beam inspection apparatus may be an imaging system (e.g., imaging system 200 in FIG. 2). The sample may be a wafer (e.g., wafer 203 in FIG. 2) with manufactured structure (e.g., circuits) on its surface. In some embodiments, the first target and the second target may be two specifically designed and manufactured structures. For example, the first target and the second target may be independent of and have no functional relationship to the manufactured circuits on the wafer. In some embodiments, the first target and the second target may be manufactured at one or more free spaces on the wafer not occupied by the manufactured circuits. In some embodiments, the first target and the second target may be adjacent to each other. In some other embodiments, the first target and the second target may be separated from each other by other manufactured structures on the sample. In some embodiments, the first target and the second target may be manufactured at a specific wafer.

The first detector signal and the second detector signal may be signals outputted by a detector (e.g., detector 206 in FIG. 2) of the charged-particle inspection apparatus in response to the first scan and the second scan, respectively. In some embodiments, the first scan and the second scan may be the same scan. For example, the first target and the second target may be scanned by a single charged-particle beam (e.g., of a single-beam inspection apparatus) or a single charged-particle beamlet (e.g., of a multi-beam inspection apparatus) in the same field of view. In some embodiments, the first scan and the second scan may be different scans. As one example, if the charged-particle inspection apparatus is a single-beam inspection apparatus (e.g., a single-beam SEM), the first target may be scanned before the second target. As another example, if the charged-particle inspection apparatus is a multi-beam inspection apparatus (e.g., a multi-beam SEM), the first target and the second target may be scanned by two different beamlets simultaneously.

During scanning the sample, after charged particles (e.g., electrons) of a primary beam (e.g., primary beam 220 in FIG. 2) hit the surface of the sample, at least one of secondary charged particles (e.g., SE 310 illustrated in FIG. 3) or backscattered charged particles (e.g., BSE 308 in FIG. 3) may be emitted from the surface of the sample and directed to the detector (e.g., detector 206 in FIG. 2). In some embodiments, at least one of secondary electrons or backscattered electrons may be emitted from the first target and directed to the detector to generate the first detector signal, and at least one of secondary electrons or backscattered electrons may also be emitted from the second target and directed to the detector to generate the second detector signal.

In some embodiments, the first detector signal and the second detector signal may be values representing sums or counts of the detected electrons emitted from the first target and the second target, respectively. In some embodiments, the first detector signal and the second detector signal may be values representing sums of charges of the detected electrons emitted from the first target and the second target, respectively. In some embodiments, the first detector signal and the second detector signal may be visualized.

In some embodiments, the first target may include a first pattern layer and a second pattern layer under the first pattern layer. The second target may include a third pattern layer and a fourth pattern layer under the third pattern layer. Pitch values of the first pattern layer and the second pattern layer may be equal to a first pitch value of the first target. Pitch values of the third pattern layer and the fourth pattern layer may also be equal to a second pitch value of the second target. In some embodiments, each of the first pattern layer, the second pattern layer, the third pattern layer, and the fourth pattern layer may include a grating.

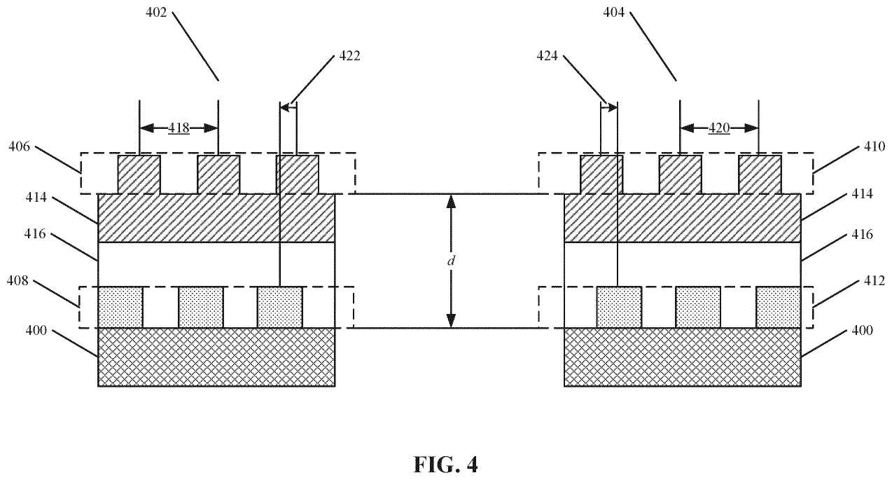

By way of example, FIG. 4 is a schematic diagram illustrating examples of a first target 402 and a second target 404 manufactured on a sample 400, consistent with some embodiments of the present disclosure. Sample 400 may be a silicon wafer substrate (represented by cross-shaded areas in FIG. 4). In some embodiments, first target 402 and second target 404 may be diffraction-based overlay targets. As illustrated in FIG. 4, first target 402 includes a first pattern layer 406 (represented by shaded areas inside a dash-box in first target 402) and a second pattern layer 408 (represented by dotted areas inside a dash-box in first target 402) under first pattern layer 406, and second target 404 includes a third pattern layer 410 (represented by shaded areas inside a dash-box in second target 404) and a fourth pattern layer 412 (represented by dotted areas inside a dash-box in second target 404) under third pattern layer 410. In FIG. 4, first pattern layer 406, second pattern layer 408, third pattern layer 410, and fourth pattern layer 412 may be of a type of a grating (e.g., a line grating).

In some embodiments, first pattern layer 406 and third pattern layer 410 may be of a material of polymethyl methacrylate (PMMA). For example, as illustrated in FIG. 4, first pattern layer 406 and third pattern layer 410 may be fabricated (e.g., via a coating, lithography, and etching process) on a PMMA layer 414 (represented by shaded areas under first pattern layer 406 and third pattern layer 410). In some embodiments, second pattern layer 408 and fourth pattern layer 412 may be of a material of copper. For example, as illustrated in FIG. 4, second pattern layer 408 and fourth pattern layer 412 may be fabricated (e.g., via a coating, lithography, and etching process) on sample 400. In some embodiments, a silicon dioxide layer 416 (represented by white areas) may separate PMMA layer 414 and second pattern layer 408, and also separate PMMA layer 414 and fourth pattern layer 412. As illustrated in FIG. 4, first pattern layer 406 and second pattern layer 408 are separated by a separation distance d, and third pattern layer 410 and fourth pattern layer 412 are also separated by separation distance d.

In FIG. 4, each of first pattern layer 406, second pattern layer 408, third pattern layer 410, and fourth pattern layer 412 may have a pitch. For example, if first pattern layer 406, second pattern layer 408, third pattern layer 410, and fourth pattern layer 412 are of a type of a grating, a pitch of any of first pattern layer 406, second pattern layer 408, third pattern layer 410, and fourth pattern layer 412 may be represented by a distance (referred to as a “pitch value” herein) between centers of two adjacent lines of the grating.

In some embodiments, pitch values of first pattern layer 406 and second pattern layer 408 may be equal to a first pitch value of first target 402. Pitch values of third pattern layer 410 and fourth pattern layer 412 may also be equal to a second pitch value of second target 404. In some embodiments, the first pitch value may be equal to the second pitch value. In some embodiments, the first pitch value may be unequal to the second pitch value. By way of example, as illustrated in FIG. 4, each of first pattern layer 406 and second pattern layer 408 may have a first pitch value 418, and each of third pattern layer 410 and fourth pattern layer 412 may have a second pitch value 420. In some embodiments, first pitch value 418 may be equal to second pitch value 420.

In some embodiments, the first pattern layer may have a first shift relative to the second pattern layer, in which the first shift may have a magnitude equal to an overlay value (e.g., a magnitude of an overlay of the sample) minus a predetermined shift value. The third pattern layer may have a second shift relative to the fourth pattern layer, in which the second shift may have a magnitude equal to the overlay value plus the predetermined shift value. A shift between two pattern layers, as used herein, refers to a horizontal distance between two corresponding structural parts on two adjacent pattern layers. For example, if the two corresponding structural parts are two corresponding grating lines, the shift between them may be a distance between the centers of the corresponding lines along a horizontal direction. In some embodiments, the shift may be represented as a vectorial displacement that has a magnitude and a direction.

By way of example, as illustrated in FIG. 4, first pattern layer 406 may have a first shift 422 (represented by a left arrow between centers of two corresponding grating lines) relative to second pattern layer 408. Third pattern layer 410 may have a second shift 424 (represented by a right arrow between centers of two corresponding grating lines) relative to fourth pattern layer 412. First shift 422 and second shift 424 may be represented as vectorial displacements that have magnitudes and directions. As illustrated in FIG. 4, first shift 422 and second shift 424 may have opposite directions. Assuming the rightward horizontal direction represents a positive direction in FIG. 4, first shift 422 may be a negative vector, and second shift 320 may be a positive vector.

Each of first shift 422 and second shift 424 in FIG. 4 may be determined based on two components. For example, assuming that sample 400 has an overlay (not illustrated in FIG. 4) that represents a vectorial, horizontal misalignment between first pattern layer 406 and second pattern layer 408 (or between third pattern layer 410 and fourth pattern layer 412) due to manufacturing errors or inaccuracies. The overlay of sample 400 may be represented as a vector that has a magnitude (i.e., the overlay value) and a direction. As illustrated in FIG. 4, assuming the overlay is a positive vector (i.e., pointing rightward), first shift 422 may have a magnitude equal to the overlay value minus a predetermined shift value (e.g., a positive value), and second shift 424 may have a magnitude equal to the overlay value plus the predetermined shift value. The predetermined shift value may be a designed or programmed shift value. In an ideal case, if the manufacturing has no error or inaccuracy, the overlay may be zero, in which first shift 422 and second shift 424 may have the same magnitude (i.e., the predetermined shift value) and opposite directions.

It should be noted that, although FIG. 4 illustrates first shift 422 and second shift 424 using first pattern layer 406 and third pattern layer 410 as static reference points, it is not so limited to prepare first target 402 and second target 404 in this disclosure. For example, to prepare first target 402 and second target 404, second pattern layer 408 and fourth pattern layer 412 may be used as static reference points, in which first pattern layer 406 may be fabricated as shifted by a predetermined shift value with respect to second pattern layer 408 in a first direction, and third pattern layer 410 may be fabricated as shifted by the predetermined shift value with respect to fourth pattern layer 412 in a second direction opposite to the first direction.

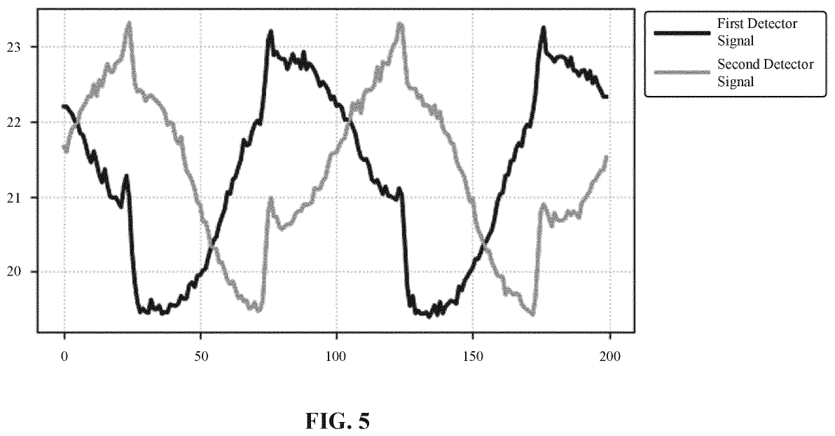

FIG. 5 is a graph 500 illustrating example visualization of a first detector signal and a second detector signal, consistent with some embodiments of the present disclosure. For example, the first detector signal in FIG. 5 may be obtained in response to a first scan of first target 402 of FIG. 4, and the second detector signal in FIG. 5 may be obtained in response to a second scan of second target 404 of FIG. 4. In graph 500, the horizontal axis may represent a distance (e.g., in a unit of pixels or nanometers), and the vertical axis may represent magnitudes of the first detector signal and the second detector signal. The first detector signal includes information (e.g., amplitude and phase information) corresponding to electrons emitted from first pattern layer 406 and information (e.g., amplitude and phase information) corresponding to electrons emitted from second pattern layer 408. The second detector signal includes information (e.g., amplitude and phase information) corresponding to electrons emitted from third pattern layer 410 and (e.g., amplitude and phase information) corresponding to electrons emitted from fourth pattern layer 412. In some embodiments, an analysis may be performed to determine the overlay value described herein based on shapes of the first detector signal and the second detector signal, which will be described below.

Consistent with some embodiments of this disclosure, the computer-implemented method of measuring overlay may also include determining a first transformed signal and a second transformed signal by performing a Fourier transform on the first detector signal and the second detector signal. In some embodiments, a first period of the first transformed signal (e.g., a first sine series or a first cosine series) may correspond to a first pitch value of the first target. A second period of the second transformed signal (e.g., a second sine series or a second cosine series) may correspond to a second pitch value of the second target. By way of example, with reference to FIG. 4, the first pitch value of the first target may be first pitch value 418, and the second pitch value of the second target may be second pitch value 420.

Consistent with some embodiments of this disclosure, the computer-implemented method of measuring overlay may further include determining, based on the first transformed signal and the second transformed signal, an overlay value of the sample.

By way of example, a Fourier transform may be performed on the first detector signal and the second detector signal (e.g., the first detector signal and the second detector signal in FIG. 5) to determine the first transformed signal and the second transformed signal. If the first pitch value (e.g., first pitch value 418) is equal to the second pitch value (e.g., second pitch value 420), a first transformed signal S₋ and a second transformed signal S₊ may be represented by Eqs. (1) and (2), respectively:

$${S}_{-} = a \cdot sin ( k x + {θ}_{a} ) + b \cdot sin ( k x + {θ}_{b -} ) \qquad Eq . ( 1 )$$

$${S}_{+} = a \cdot sin ( k x + {θ}_{a} ) + b \cdot sin ( k x + {θ}_{b +} ) \qquad Eq . ( 2 )$$

In Eq. (1), a·sin(kx+θₐ) represents a sine series of a first signal corresponding to the electrons emitted from first pattern layer 406, in which a represents an amplitude of the first signal,

$$\frac{2 π}{k}$$

represents a period that corresponds to the first pitch value (i.e., equal to the second pitch value), and θₐ represents a phase term of the first signal. Also, in Eq. (1), b·sin(kx+θ_{b-}) represents a sine series of a second signal corresponding to the electrons emitted from second pattern layer 408, in which b represents an amplitude of the second signal,

$$\frac{2 π}{k}$$

represents a period that corresponds to the second pitch value (i.e., equal to the first pitch value), and θ_{b-} represents a phase term of the second signal. In Eq. (2), a·sin(kx+θₐ) represents a sine series of a third signal corresponding to the electrons emitted from third pattern layer 410, and b·sin(kx+θ_{b+}) represents a sine series of a fourth signal corresponding to the electrons emitted from fourth pattern layer 412, in which θ_{b+} represents a phase term of the fourth signal.

The phase terms θ_{b-} and θ_{b+} may be represented by Eqs. (3) and (4), respectively:

$${θ}_{b -} = {θ}_{a} + ϕ - ψ \qquad Eq . ( 3 )$$

$${θ}_{b +} = {θ}_{a} + ϕ + ψ \qquad Eq . ( 4 )$$

In Eqs. (3)-(4), ψ represents a phase term contributed by the predetermined shift value described herein, and ϕ represents a phase term contributed by the overlay value. The phase value ϕ may represent a partial phase difference between the first transformed signal S₋ and the second transformed signal S₊. Because the predetermined shift value is known, the value of ψ may be deduced in Eqs. (3)-(4).

Assuming S₋ of Eq. (1) and S₊ of Eq. (2) may be equivalent to two signals in complex space as expressed in Eqs. (5)-(6), and a difference signal S_{±} may be determined as a differential signal (e.g., by subtraction) as expressed in Eq. (7):

$${S}_{-} = a \cdot sin ( k x + {θ}_{a} ) + b \cdot sin ( k x + {θ}_{b -} ) {=}^{△} {C}_{-} \cdot sin ( k x + {θ}_{A} ) \qquad Eq . ( 5 )$$

$${S}_{+} = a \cdot sin ( k x + {θ}_{a} ) + b \cdot sin ( k x + {θ}_{b +} ) {=}^{△} {C}_{+} \cdot sin ( k x + {θ}_{B} ) \qquad Eq . ( 6 )$$

$${S}_{\pm } = {S}_{+} - {S}_{-} {=}^{△} {C}_{Δ} \cdot cos ( k x + {θ}_{a} + ϕ ) \qquad Eq . ( 7 )$$

$$where$$

$${C}_{+}^{2} = {a}^{2} + {b}^{2} + 2 \cdot a \cdot b \cdot cos ( - ϕ - ψ ) \qquad Eq . ( 8 )$$

$${C}_{-}^{2} = {a}^{2} + {b}^{2} + 2 \cdot a \cdot b \cdot cos ( - ϕ + ψ ) \qquad Eq . ( 9 )$$

$${C}_{Δ} = 2 \cdot b \cdot sin ψ \qquad Eq . ( 10 )$$

In Eqs. (5)-(10), C₋, C₊, and C_{Δ} are referred to as a first amplitude, a second amplitude, and a third amplitude, respectively. Because C₋ and C₊ are related to amplitudes of the first detector signal and the second detector signal (e.g., the first detector signal and the second detector signal in FIG. 5) by the Fourier transform, and because the amplitudes of the first detector signal and the second detector signal are measurable, C₋ may be determined based on Eq. (5) and the measured amplitude of the first detector signal, and C+ may be determined based on Eq. (6) and the measured amplitude of the second detector signal.

C_{Δ} may be determined in different manners. For example, after determining C₋ and C₊, S_{±} may be determined using Eq. (7) analytically, based on which C_{Δ} may also be determined analytically. As another example, a difference detector signal may first be determined (e.g., by subtraction) based on a difference between the first detector signal and the second detector signal (e.g., the first detector signal and the second detector signal in FIG. 5), and then a Fourier transform may be applied to the difference detector signal. In such a case, C_{Δ} may be determined as the norm of the Fourier-transformed difference detector signal.

Based on Eqs. (5)-(10), Eqs. (1)-(4) may be converted into a quadratic function of tan ϕ represented by Eq. (11), in which ϕ is the only unknown variable:

$$Eq . ( 11 )$$

$$[ {C}_{+}^{2} + {C}_{-}^{2} - 2 \cdot {F}^{2} - \frac{1}{2} \cdot \frac{{C}_{Δ}^{2}}{{sin}^{2} ψ} ] \cdot {tan}^{2} ϕ - \frac{2 \cdot F \cdot {C}_{Δ}}{tan ψ} \cdot tan ϕ - 2 \cdot {F}^{2} = 0$$

$$where$$

$$F = \frac{{C}_{-}^{2} - {C}_{+}^{2}}{2 \cdot {C}_{Δ}} \qquad Eq . ( 12 )$$

In some embodiments, to determine the overlay value, the computer-implemented method may include determining a first amplitude value of the first transformed signal, a second amplitude value of the second transformed signal, and a third amplitude value associated with a difference between the first transformed signal and the second transformed signal. Then, a phase value representing a partial phase difference between the first transformed signal and the second transformed signal may be determined. After that, the overlay value of the sample may be determined based on the phase value and the first pitch value (i.e., equal to the second pitch value).

By way of example, the first transformed signal and the second transformed signal may be the S₋ and S₊ described in association with Eq. (1) and (2), respectively. The first amplitude value, the second amplitude value, and the third amplitude value may be the C₋, C₊, and C_{Δ} described in association with Eqs. (5)-(12). The phase value may be the value of ϕ determined from solving Eq. (11). If the first pitch value (e.g., first pitch value 418) and the second pitch value (e.g., second pitch value 420) are equal and known (e.g., equal to a value of P), the overlay value may be determined as

$$\frac{ϕ}{2 π} \cdot P .$$

The example method described in association with FIGS. 4-5 and Eqs. (1)-(12) may have the first target and the second target manufactured at one or more free spaces on the wafer not occupied by the manufactured circuits. When there is not sufficient space to manufacture two targets on the wafer, a single target may also be used to measure an overlay of a sample, which will be described below.

Consistent with some embodiments of this disclosure, another computer-implemented method of measuring overlay for a sample under a scan performed by a charged-particle beam inspection apparatus may include obtaining a detector signal in response to a scan of a target of the sample. In some embodiments, the charged-particle beam inspection apparatus may include a scanning electron microscope. The sample may include a wafer.

By way of example, the charged-particle beam inspection apparatus may be an imaging system (e.g., imaging system 200 in FIG. 2). The sample may be a wafer (e.g., wafer 203 in FIG. 2) with manufactured structure (e.g., circuits) on its surface. In some embodiments, the target may be a specifically designed and manufactured structure. For example, the target may be independent of and has no functional relationship to the manufactured circuits on the wafer. In some embodiments, the target may be manufactured at a free space on the wafer not occupied by the manufactured circuits.

The detector signal may be a signal outputted by a detector (e.g., detector 206 in FIG. 2) of the charged-particle inspection apparatus in response to the scan. In some embodiments, the target may be scanned by a charged-particle beam (e.g., of a single-beam inspection apparatus) or a charged-particle beamlet (e.g., of a multi-beam inspection apparatus). During scanning of the sample, after charged particles (e.g., electrons) of a primary beam (e.g., primary beam 220 in FIG. 2) hit the surface of the sample, at least one of secondary charged particles (e.g., SE 310 illustrated in FIG. 3) or backscattered charged particles (e.g., BSE 308 in FIG. 3) may be emitted from the surface of the sample and directed to the detector (e.g., detector 206 in FIG. 2). In some embodiments, at least one of secondary electrons or backscattered electrons may be emitted from the target and directed to the detector to generate the detector signal.

In some embodiments, the detector signal may be a value representing a sum or a count of the detected electrons emitted from the target. In some embodiments, the detector signal may be a value representing a sum of charges of the detected electrons emitted from the target. In some embodiments, the detector signal may be visualized.

In some embodiments, the target may include a first pattern layer and a second pattern layer under the first pattern layer. Pitch values of the first pattern layer and the second pattern layer may be to a pitch value of the target. The first pattern layer may have no predetermined shift relative to the second pattern layer. In some embodiments, each of the first pattern layer and the second pattern layer may include a grating.

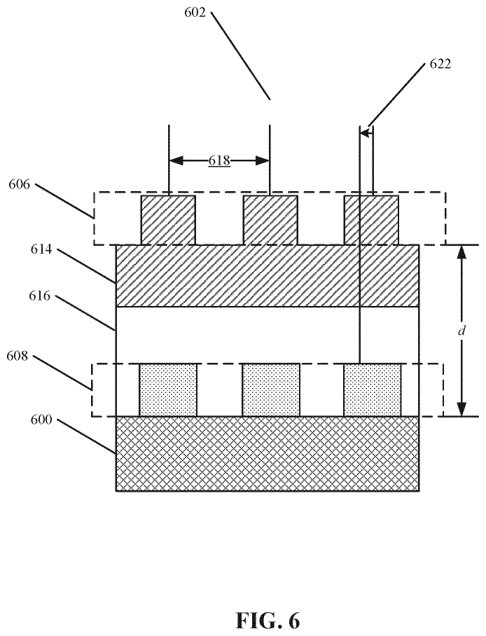

By way of example, FIG. 6 is a schematic diagram illustrating an example target 602 manufactured on a sample 600, consistent with some embodiments of the present disclosure. Sample 600 may be a silicon wafer substrate (represented by cross-shaded areas in FIG. 6). In some embodiments, target 602 may be diffraction-based overlay targets. As illustrated in FIG. 6, target 602 includes a first pattern layer 606 (represented by shaded areas inside a dash-box in target 602) and a second pattern layer 608 (represented by dotted areas inside a dash-box in target 602) under first pattern layer 606. In FIG. 6, first pattern layer 606 and second pattern layer 608 may be of a type of a grating (e.g., a line grating). In some embodiments, first pattern layer 606 may be of a material of polymethyl methacrylate (PMMA). For example, as illustrated in FIG. 6, first pattern layer 606 may be fabricated (e.g., via a coating, lithography, and etching process) on a PMMA layer 614 (represented by shaded areas under first pattern layer 606 and third pattern layer 610). In some embodiments, second pattern layer 608 may be of a copper material. For example, as illustrated in FIG. 6, second pattern layer 608 may be fabricated (e.g., via a coating, lithography, and etching process) on sample 600. In some embodiments, a silicon dioxide layer 616 (represented by white areas) may separate PMMA layer 614 and second pattern layer 608. As illustrated in FIG. 6, first pattern layer 606 and second pattern layer 608 are separated by a separation distance d.

In FIG. 6, each of first pattern layer 606 and second pattern layer 608 may have a pitch. For example, if first pattern layer 606 and second pattern layer 608 are of a type of a grating, a pitch of either of first pattern layer 606 and second pattern layer 608 may be represented by a distance (referred to as a “pitch value” herein) between centers of two adjacent lines of the grating. In some embodiments, pitch values of first pattern layer 606 and second pattern layer 608 may be equal to a pitch value of the target. By way of example, as illustrated in FIG. 6, each of first pattern layer 606 and second pattern layer 608 may have a pitch value 618.

In some embodiments, the first pattern layer may have a shift relative to the second pattern layer, in which the shift may have a magnitude equal to an overlay value (e.g., a magnitude of an overlay of the sample) plus or minus a predetermined shift value. In some embodiments, the shift may be represented as a vectorial displacement that has a magnitude and a direction.

By way of example, as illustrated in FIG. 6, first pattern layer 606 may have a shift 622 (represented by a left arrow between centers of two corresponding grating lines, not in scale in FIG. 6) relative to second pattern layer 608. Shift 622 may be represented as vectorial displacements that have magnitudes and directions. Assuming the rightward horizontal direction represents a positive direction in FIG. 6, shift 622 may be a negative vector. Assuming that sample 600 has an overlay (not illustrated in FIG. 6) that represents a vectorial, horizontal misalignment between first pattern layer 606 and second pattern layer 608 due to manufacturing errors or inaccuracies. The overlay of sample 600 may be represented as a vector that has a magnitude (i.e., the overlay value) and a direction. As illustrated in FIG. 6, assuming the overlay is a positive vector (i.e., pointing rightward), shift 622 may have a magnitude equal to the overlay value plus or minus a predetermined shift value (e.g., a positive value). The predetermined shift value may be a designed or programmed shift value. In an ideal case, if the manufacturing has no error or inaccuracy, the overlay may be zero, in which shift 622 may have its magnitude equal to the predetermined shift value. In FIG. 6, the predetermined shift value is zero, and shift 622 represents the overlay of the sample.

Consistent with some embodiments of this disclosure, the computer-implemented method of measuring overlay may also include determining a first transformed signal by performing a Fourier transform on the detector signal and a second transformed signal by converting the first transformed signal. In some embodiments, a period of the first transformed signal (e.g., a first sine series or a first cosine series) and a period of the second transformed signal (e.g., a second sine series or a second cosine series) may correspond to a pitch value of the target. By way of example, with reference to FIG. 6, the pitch value of the target may be pitch value 618.

Consistent with some embodiments of this disclosure, the computer-implemented method of measuring overlay may further include determining an overlay value of the sample based on the first transformed signal, the second transformed signal, a first predetermined amplitude value, and a second predetermined amplitude value. In some embodiments, the first predetermined amplitude value and the second predetermined amplitude value may be associated with two targets adjacent to the target.

By way of example, a Fourier transform may be performed on the detector signal to determine a first transformed signal S₁ represented by Eq. (13):

$${S}_{1} = a \cdot sin ( x + {θ}_{a} ) + b \cdot sin ( x + {θ}_{b} ) \qquad Eq . ( 13 )$$

In Eq. (13), a·sin(x+θₐ) represents a sine series of a first signal corresponding to the electrons emitted from first pattern layer 606 and has a period that corresponds to the pitch value (e.g., pitch value 618), in which a represents an amplitude of the first signal, and θₐ represents a phase term of the first signal. Also, in Eq. (13), b·sin(x+θ_{b}) represents a sine series of a second signal corresponding to the electrons emitted from second pattern layer 608 and has a period that corresponds to the pitch value (e.g., pitch value 618), in which b represents an amplitude of the second signal, and θ_{b} represents a phase term of the second signal.

By way of example, the first transformed signal S₁ represented by Eq. (13) may be converted (e.g., by summing a·sin(x+θₐ) and b·sin(x+θ_{b})) to generate a second transformed signal S₂ represented by Eq. (14):

$${S}_{2} = c \cdot sin ( x + φ ) \qquad Eq . ( 14 )$$

In Eq. (14), c represents a third amplitude value (e.g., representing an amplitude of the summed signal), and φ represents a phase term contributed by the sum of two waves a·sin(x+θₐ) and b·sin(x+θ_{b}). The overlay value is related to a phase difference (θₐ−θ_{b}). By equating S₁ and S₂, the following may be deduced:

$$a \cdot sin ( x + {θ}_{α} ) + b \cdot sin ( x + {θ}_{b} ) = c \cdot sin ( x + φ ) \qquad Eq . ( 15 )$$

$${c}^{2} = {a}^{2} + {b}^{2} + 2 \cdot a \cdot b \cdot cos ( {θ}_{a} - {θ}_{b} ) \qquad Eq . ( 16 )$$

$$tan φ = \frac{a \cdot sin {θ}_{a} + b \cdot sin {θ}_{b}}{a \cdot cos {θ}_{a} + b \cdot cos {θ}_{b}} \qquad Eq . ( 17 )$$

In some embodiments, the value of tan ϕ may be determined based on measurement of the detector signal, the Fourier transform of which is the first transformed signal S₁. It should be noted that the first amplitude value a and the second amplitude value b cannot be solved by Eqs. (13)-(17) themselves. In some embodiments, the a and b in Eq. (16)-(17) may be substituted by a first predetermined amplitude value a′ and a second predetermined amplitude value b′, both a′ and b′ may be solved based on Eqs. (1)-(12).

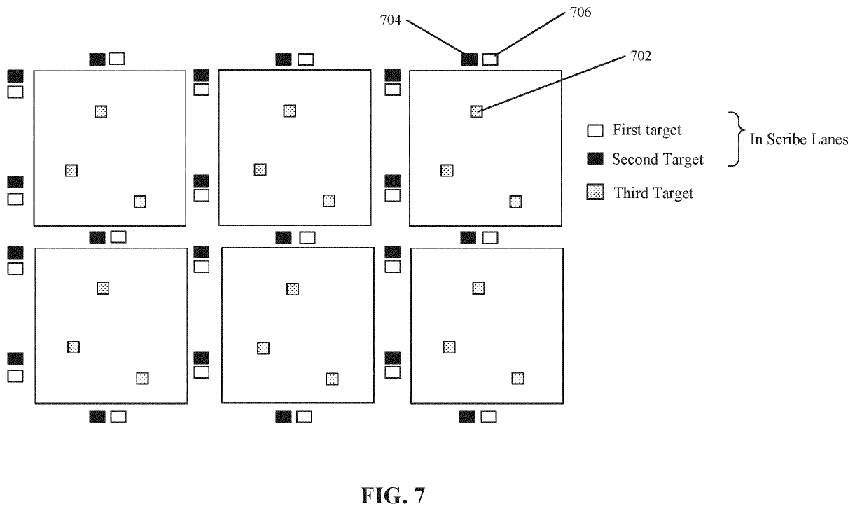

By way of example, FIG. 7 is a schematic diagram illustrating an example arrangement 700 of targets manufactured on a sample, consistent with some embodiments of the present disclosure. As depicted in FIG. 7, the large white boxes represent manufactured devices (e.g., integrated circuits) on a sample (e.g., sample 500 of FIG. 5 or sample 600 of FIG. 6). The space between two adjacent large white boxes may be referred to as a scribe lane in this disclosure. As an example, arrangement 700 depicts one horizontal scribe lane and two vertical scribe lanes. In the scribe lanes, pairs of first targets and second targets may be manufactured. In FIG. 7, as an example, the first targets may be manufactured similar to first target 402 (with first shift 422) of FIG. 4, and the second targets may be manufactured similar to second target 404 (with second shift 424) of FIG. 4. The first targets in arrangement 700 may be represented by small white boxes, and the second targets in arrangement 700 may be represented by small black boxes, as indicated by the legends of FIG. 7.

To determine overlay values for the manufactured devices depicted in arrangement 700, third targets (or referred to as “in-device targets”) may be manufactured within the devices, represented by the dotted boxes in FIG. 7. The third targets may be manufactured without programmed shifts, similar to target 602 (with shift 622) of FIG. 6. The overlay value of the devices (e.g., represented by shift 622) may be determined using the example method described in association with Eqs. (13)-(17), in which the values of a, b, and (θₐ−θ_{b}) are unknown. In such a case, the example method described in association with Eqs. (1)-(12) may be used to generate the first predetermined amplitude value a′ and the second predetermined amplitude value b′ for pairs of the first targets and the second targets adjacent to the third targets.

For example, with reference to FIG. 7, the example method described in association with Eqs. (13)-(17) may be applied to a third target 702 to generate a value of tan ϕ expressed in Eq. (17), in which the values of a, b, and (θₐ−θ_{b}) associated with third target 702 are unknown. However, the example method described in association with Eqs. (1)-(12) may be applied to a pair of a first target 704 and a second target 706, in which the first predetermined amplitude value a′ (corresponding to the value of a in Eqs. (1)-(12)) and the second predetermined amplitude value b′ (corresponding to the value of b in Eqs. (1)-(12)) may be determined (e.g., deduced from Eqs. (8)-(9) with known values of C₋, C₊, C_{Δ}, ψ and ϕ).

The first predetermined amplitude value a′ and the second predetermined amplitude value b′ may be used to determine the unknown values of a and b associated with third target 702, respectively. For example, the unknown values of a and b associated with third target 702 may be determined by interpolating the first predetermined amplitude value a′ and the second predetermined amplitude value b′ of multiple pairs of the first targets and the second targets (including the pair of first target 704 and second target 706). As another example, the unknown values of a and b associated with third target 702 may be determined as the first predetermined amplitude value a′ and the second predetermined amplitude value b′ determined from the pair of first target 704 and second target 706.

Further, based on an amplitude of a detector signal corresponding to third target 702, an amplitude (e.g., corresponding to c in Eq. (14)) of a Fourier-transform signal (e.g., corresponding to S₂ in Eq. (14)) of the detector signal may be determined. With reference to Eq. (16), for third target 702, c has been determined, and a and b have been determined based on a′ and b′ as described herein, therefore, the value of (θₐ−θ_{b}) may also be determined. The overlay value of target 702 (that represents the overlay value of the manufactured device where target 702 sits in) may be determined as

$$\frac{{θ}_{a} - {θ}_{b}}{2 π} \cdot P ,$$

in which P represents a known pitch value (e.g., similar to pitch value 618 of FIG. 6) of third target 702.

Alternatively, to determine the overlay value of target 702, after determining the values of a, b, and c (e.g., in a manner described in association with FIG. 7), the value of (θₐ−θ_{b}) may be determined using Eq. (16). Next, the value of 02 may be determined (e.g., using an edge detection technique) based on a secondary-electron signal corresponding to target 702, in which the secondary-electron signal may represent the secondary electrons emitted from a first pattern layer of target 702 (e.g., similar to first pattern layer 606 of FIG. 6) and have significant peaks. After determining the values of θₐ and tan , the value of θ_{b} may also be determined from Eq. (17) (because θ_{b} is the only remaining unknown parameter). Then, the overlay value of target 702 (that represents the overlay value of the manufactured device where target 702 sits in) may be determined as

$$\frac{{θ}_{α} - {θ}_{b}}{2 π} \cdot P ,$$

in which P represents a known pitch value (e.g., similar to pitch value 618 of FIG. 6) of third target 702.

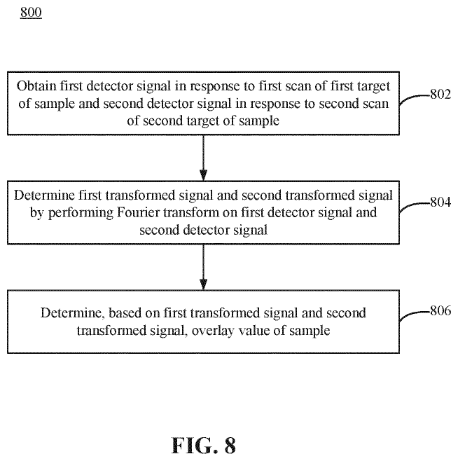

By way of example, FIG. 8 is a flowchart illustrating an example method 800 for overlay measurement, consistent with some embodiments of the present disclosure. Method 800 may be performed by a controller that may be coupled with a charged-particle beam inspection apparatus (e.g., charged-particle beam inspection system 100). For example, the controller may be controller 109 in FIG. 2. The controller may be programmed to implement method 800.

At step 802, the controller may obtain a first detector signal (e.g., the first detector signal visualized in FIG. 5) in response to a first scan (e.g., by a single-beam inspection apparatus or a multi-beam inspection apparatus) of a first target (e.g., first target 402 of FIG. 4) of a sample (e.g., sample 400 of FIG. 4) and a second detector signal (e.g., the second detector signal visualized in FIG. 5) in response to a second scan (e.g., by a single-beam inspection apparatus or a multi-beam inspection apparatus) of a second target (e.g., second target 404 of FIG. 4) of the sample. In some embodiments, the charged-particle beam inspection apparatus may include a scanning electron microscope. By way of example, the sample may include a wafer.

In some embodiments, the first target may include a first pattern layer (e.g., first pattern layer 406 of FIG. 4) and a second pattern layer (e.g., second pattern layer 408 of FIG. 4) under the first pattern layer. The second target may include a third pattern layer (e.g., third pattern layer 410 of FIG. 4) and a fourth pattern layer (e.g., fourth pattern layer 412 of FIG. 4) under the third pattern layer. Pitch values of the first pattern layer and the second pattern layer may be equal to a first pitch value (e.g., first pitch value 418 of FIG. 4) of the first target. Pitch values of the third pattern layer and the fourth pattern layer may also be equal to a second pitch value (e.g., second pitch value 420 of FIG. 4) of the second target. In some embodiments, each of the first pattern layer, the second pattern layer, the third pattern layer, and the fourth pattern layer may include a grating (e.g., a line grating).

In some embodiments, the first pattern layer may have a first shift (e.g., first shift 422 of FIG. 4) relative to the second pattern layer, in which the first shift may have a magnitude equal to an overlay value (e.g., a magnitude of an overlay of the sample) minus a predetermined shift value. The third pattern layer may have a second shift (e.g., second shift 424 of FIG. 4) relative to the fourth pattern layer, in which the second shift may have a magnitude equal to the overlay value plus the predetermined shift value.

At step 804, the controller may determine a first transformed signal (e.g., S₋ described in association with Eq. (1)) and a second transformed signal (e.g., S₊ described in association with Eq. (2)) by performing a Fourier transform on the first detector signal and the second detector signal. In some embodiments, a first period (e.g.,

$$\frac{2 π}{k}$$

described in association with EQ. (1)) of the first transformed signal may correspond to the first pitch value (e.g., first pitch value 418 of FIG. 4) of the first target, and a second period (e.g.,

$$\frac{2 π}{k}$$

described in association with Eq. (2)) of the second transformed signal may correspond to a second pitch value (e.g., second pitch value 420 of FIG. 4) of the second target. In some embodiments, the first pitch value may be equal to the second pitch value.

At step 806, the controller may determine, based on the first transformed signal and the second transformed signal, an overlay value (e.g., based on tan ϕ described in association with Eqs. (3)-(12)) of the sample. In some embodiments, when the first pitch value may be equal to the second pitch value (e.g., both being a pitch value of P) to determine the overlay value at step 806, the controller may determine a first amplitude value (e.g., C₋ described in association with Eqs. (5)-(12)) of the first transformed signal, a second amplitude value (e.g., C₊ described in association with Eqs. (5)-(12)) of the second transformed signal, and a third amplitude value (e.g., C_{Δ} described in association with Eqs. (5)-(12)) associated with a difference (e.g., S_{±} described in association with Eqs. (5)-(12)) between the first transformed signal and the second transformed signal. Then, the controller may determine a phase value (e.g., ϕ described in association with Eqs. (1)-(12)) representing a partial phase difference between the first transformed signal and the second transformed signal. After that, the controller may determine the overlay value

$$( e . g . , as \frac{ϕ}{2 π} \cdot P )$$

of the sample based on the first amplitude value and the first pitch value.

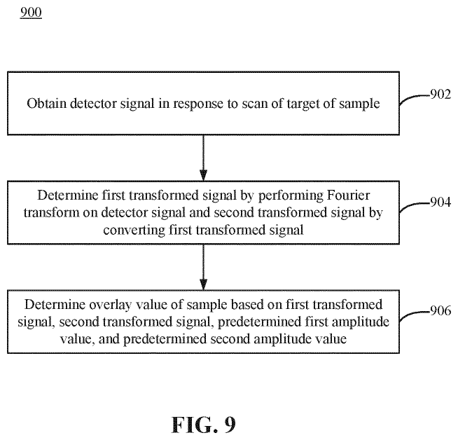

FIG. 9 is a flowchart illustrating another example method 900 for overlay measurement, consistent with some embodiments of the present disclosure. Method 900 may be performed by a controller that may be coupled with a charged-particle beam inspection apparatus (e.g., charged-particle beam inspection system 100). For example, the controller may be controller 109 in FIG. 2. The controller may be programmed to implement method 900.

At step 902, the controller may obtain a detector signal in response to a scan (e.g., by a single-beam inspection apparatus or a multi-beam inspection apparatus) of a target (e.g., target 602 of FIG. 6) of a sample (e.g., sample 600 of FIG. 6). In some embodiments, the charged-particle beam inspection apparatus may include a scanning electron microscope. By way of example, the sample may include a wafer.

In some embodiments, the first target may include a first pattern layer (e.g., first pattern layer 606 of FIG. 6) and a second pattern layer (e.g., second pattern layer 608 of FIG. 6) under the first pattern layer. Pitch values of the first pattern layer and the second pattern layer may be equal to a pitch value (e.g., pitch value 618 of FIG. 6) of the target. The first pattern layer may have no predetermined shift relative to the second pattern layer. In some embodiments, each of the first pattern layer and the second pattern layer may include a grating (e.g., a line grating).

At step 904, the controller may determine a first transformed signal (e.g., S₁ described in association with Eq. (13)) by performing a Fourier transform on the first detector signal and a second transformed signal (e.g., S₂ described in association with Eq. (14)) by converting the first transformed signal. In some embodiments, a period of the first transformed signal and a period of the second transformed signal may correspond to a pitch value (e.g., pitch value 618 of FIG. 6) of the target.

At step 906, the controller may determine an overlay value (e.g., the overlay value corresponding to tan ϕ described in association with Eqs. (17)-(20)) of the sample based on the first transformed signal, the second transformed signal, a first predetermined amplitude value, and a second predetermined amplitude value. In some embodiments, the first predetermined amplitude value (e.g., a′ determined using Eqs. (1)-(9)) and the second predetermined amplitude value (e.g., b′ determined using Eqs. (1)-(9)) may be associated with two targets adjacent to the target. For example, the target (e.g., target 602 described in association with FIG. 6) may be in a first space (e.g., a die) that is sufficient to fabricate a single target, and the two targets (e.g., first target 402 and second target 404 described in association with FIG. 4) may be in a second space (e.g., a scribe line) adjacent to the first space and is sufficient to fabricate the two targets. Both the first space and the second space are on the same sample.

A non-transitory computer readable medium may be provided that stores instructions for a processor (for example, processor of controller 109 of FIG. 1) to carry out overlay measurement such as method 800 of FIG. 8 or method 900 of FIG. 9, data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments can further be described using the following clauses:
1. A system, comprising:
a charged-particle beam inspection apparatus configured to scan a sample; and
a controller including circuitry, configured to:
obtain a first detector signal in response to a first scan of a first target of the sample and a second detector signal in response to a second scan of a second target of the sample;
determine a first transformed signal and a second transformed signal by performing a Fourier transform on the first detector signal and the second detector signal; and
determine, based on the first transformed signal and the second transformed signal, an overlay value of the sample.
2. The system of clause 1, wherein a first period of the first transformed signal corresponds to a first pitch value of the first target, and a second period of the second transformed signal corresponds to a second pitch value of the second target.
3. The system of any of clauses 1-2, wherein the charged-particle beam inspection apparatus comprises a scanning electron microscope, and the sample comprises a wafer.
4. The system of any of clauses 1-3, wherein the first target comprises a first pattern layer and a second pattern layer under the first pattern layer,
the second target comprises a third pattern layer and a fourth pattern layer under the third pattern layer, pitch values of the first pattern layer and the second pattern layer are equal to a first pitch value of the first target, and
pitch values of the third pattern layer and the fourth pattern layer are equal to a second pitch value of the second target.
5. The system of clause 4, wherein each of the first pattern layer, the second pattern layer, the third pattern layer, and the fourth pattern layer comprises a grating.
6. The system of any of clauses 4-5, wherein the first pattern layer has a first shift relative to the second pattern layer, wherein the first shift has a magnitude equal to the overlay value minus a predetermined shift value,
the third pattern layer has a second shift relative to the fourth pattern layer, wherein the second shift has a magnitude equal to the overlay value plus the predetermined shift value.
7. The system of any of clauses 4-5, wherein the first pitch value is equal to the second pitch value.
8. The system of clause 7, wherein the controller is further configured to:
determine a first amplitude value of the first transformed signal, a second amplitude value of the second transformed signal, and a third amplitude value associated with a difference between the first transformed signal and the second transformed signal;
determine a phase value representing a partial phase difference between the first transformed signal and the second transformed signal; and
determine the overlay value of the sample based on the phase value and the first pitch value.
9. A non-transitory computer-readable medium that stores a set of instructions that is executable by at least one processor of an apparatus to cause the apparatus to perform a method, the method comprising:
obtaining a first detector signal in response to a first scan of a first target of a sample scanned by a charged-particle beam inspection apparatus and a second detector signal in response to a second scan of a second target of the sample;
determining a first transformed signal and a second transformed signal by performing a Fourier transform on the first detector signal and the second detector signal; and
determining, based on the first transformed signal and the second transformed signal, an overlay value of the sample.
10. The non-transitory computer-readable medium of clause 9, wherein a first period of the first transformed signal corresponds to a first pitch value of the first target, and a second period of the second transformed signal corresponds to a second pitch value of the second target.
11. The non-transitory computer-readable medium of any of clauses 9-10, wherein the charged-particle beam inspection apparatus comprises a scanning electron microscope, and the sample comprises a wafer.
12. The non-transitory computer-readable medium of any of clauses 9-11, wherein the first target comprises a first pattern layer and a second pattern layer under the first pattern layer,
the second target comprises a third pattern layer and a fourth pattern layer under the third pattern layer, pitch values of the first pattern layer and the second pattern layer are equal to a first pitch value of the first target, and
pitch values of the third pattern layer and the fourth pattern layer are equal to a second pitch value of the second target.
13. The non-transitory computer-readable medium of clause 12, wherein each of the first pattern layer, the second pattern layer, the third pattern layer, and the fourth pattern layer comprises a grating.
14. The non-transitory computer-readable medium of any of clauses 12-13, wherein the first pattern layer has a first shift relative to the second pattern layer, wherein the first shift has a magnitude equal to the overlay value minus a predetermined shift value, the third pattern layer has a second shift relative to the fourth pattern layer, wherein the second shift has a magnitude equal to the overlay value plus the predetermined shift value.
15. The non-transitory computer-readable medium of any of clauses 12-14, wherein the first pitch value is equal to the second pitch value.
16. The non-transitory computer-readable medium of clause 15, wherein determining, based on the first transformed signal and the second transformed signal, the overlay value of the sample comprises:
determining a first amplitude value of the first transformed signal, a second amplitude value of the second transformed signal, and a third amplitude value associated with a difference between the first transformed signal and the second transformed signal;
determining a phase value representing a partial phase difference between the first transformed signal and the second transformed signal; and
determining the overlay value of the sample based on the phase value and the first pitch value.
17. A computer-implemented method of measuring overlay for a sample under a scan performed by a charged-particle beam inspection apparatus, comprising:
obtaining a first detector signal in response to a first scan of a first target of the sample and a second detector signal in response to a second scan of a second target of the sample;
determining a first transformed signal and a second transformed signal by performing a Fourier transform on the first detector signal and the second detector signal; and
determining, based on the first transformed signal and the second transformed signal, an overlay value of the sample.
18. The computer-implemented method of clause 17, wherein a first period of the first transformed signal corresponds to a first pitch value of the first target, and a second period of the second transformed signal corresponds to a second pitch value of the second target.
19. The computer-implemented method of any of clauses 17-18, wherein the charged-particle beam inspection apparatus comprises a scanning electron microscope, and the sample comprises a wafer.
20. The computer-implemented method of any of clauses 17-19, wherein the first target comprises a first pattern layer and a second pattern layer under the first pattern layer,
the second target comprises a third pattern layer and a fourth pattern layer under the third pattern layer, pitch values of the first pattern layer and the second pattern layer are equal to a first pitch value of the first target, and
pitch values of the third pattern layer and the fourth pattern layer are equal to a second pitch value of the second target.
21. The computer-implemented method of clause 20, wherein each of the first pattern layer, the second pattern layer, the third pattern layer, and the fourth pattern layer comprises a grating.
22. The computer-implemented method of any of clauses 20-21, wherein the first pattern layer has a first shift relative to the second pattern layer, wherein the first shift has a magnitude equal to the overlay value minus a predetermined shift value,
the third pattern layer has a second shift relative to the fourth pattern layer, wherein the second shift has a magnitude equal to the overlay value plus the predetermined shift value.
23. The computer-implemented method of any of clauses 20-22, wherein the first pitch value is equal to the second pitch value.
24. The computer-implemented method of clause 23, wherein determining, based on the first transformed signal and the second transformed signal, the overlay value of the sample comprises:
determining a first amplitude value of the first transformed signal, a second amplitude value of the second transformed signal, and a third amplitude value associated with a difference between the first transformed signal and the second transformed signal;
determining a phase value representing a partial phase difference between the first transformed signal and the second transformed signal; and
determining the overlay value of the sample based on the phase value and the first pitch value.
25. A system, comprising:
a charged-particle beam inspection apparatus configured to scan a sample; and
a controller including circuitry, configured to:
obtain a detector signal in response to a scan of a target of the sample;
determine a first transformed signal by performing a Fourier transform on the detector signal and a second transformed signal by converting the first transformed signal; and
determine an overlay value of the sample based on the first transformed signal, the second transformed signal, a first predetermined amplitude value, and a second predetermined amplitude value.
26. The system of clause 25, wherein the first predetermined amplitude value and the second predetermined amplitude value are associated with two targets adjacent to the target.
27. The system of any of clauses 25-26, wherein a period of the first transformed signal and a period of the second transformed signal correspond to a pitch value of the target.
28. The system of any of clauses 25-27, wherein the charged-particle beam inspection apparatus comprises a scanning electron microscope, and the sample comprises a wafer.
29. The system of any of clauses 25-28, wherein the target comprises a first pattern layer and a second pattern layer under the first pattern layer,
pitch values of the first pattern layer and the second pattern layer are equal to a pitch value of the target, and the first pattern layer has no predetermined shift relative to the second pattern layer.
30. The system of clause 29, wherein each of the first pattern layer and the second pattern layer comprises a grating.
31. A non-transitory computer-readable medium that stores a set of instructions that is executable by at least one processor of an apparatus to cause the apparatus to perform a method, the method comprising:
obtaining a detector signal in response to a scan of a target of a sample scanned by a charged-particle beam inspection apparatus;
determining a first transformed signal by performing a Fourier transform on the detector signal and a second transformed signal by converting the first transformed signal; and
determining an overlay value of the sample based on the first transformed signal, the second transformed signal, a first predetermined amplitude value, and a second predetermined amplitude value.
32. The non-transitory computer-readable medium of clause 31, wherein the first predetermined amplitude value and the second predetermined amplitude value may be associated with two targets adjacent to the target.
33. The non-transitory computer-readable medium of any of clauses 31-32, wherein a period of the first transformed signal and a period of the second transformed signal correspond to a pitch value of the target.
34. The non-transitory computer-readable medium of any of clauses 31-33, wherein the charged-particle beam inspection apparatus comprises a scanning electron microscope, and the sample comprises a wafer.
35. The non-transitory computer-readable medium of any of clauses 31-34, wherein the target comprises a first pattern layer and a second pattern layer under the first pattern layer,
pitch values of the first pattern layer and the second pattern layer are equal to a pitch value of the target, and
the first pattern layer has no predetermined shift relative to the second pattern layer.
36. The non-transitory computer-readable medium of any of clauses 31-35, wherein each of the first pattern layer and the second pattern layer comprises a grating.
37. A computer-implemented method of measuring overlay for a sample under a scan performed by a charged-particle beam inspection apparatus, comprising:
obtaining a detector signal in response to a scan of a target of the sample;
determining a first transformed signal by performing a Fourier transform on the detector signal and a second transformed signal by converting the first transformed signal; and
determining an overlay value of the sample based on the first transformed signal, the second transformed signal, a first predetermined amplitude value, and a second predetermined amplitude value.
38. The computer-implemented method of clause 37, wherein the first predetermined amplitude value and the second predetermined amplitude value are associated with two targets adjacent to the target.
39. The computer-implemented method of any of clauses 37-38, wherein a period of the first transformed signal and a period of the second transformed signal correspond to a pitch value of the target.
40. The computer-implemented method of any of clauses 37-39, wherein the charged-particle beam inspection apparatus comprises a scanning electron microscope, and the sample comprises a wafer.
41. The computer-implemented method of any of clauses 37-40, wherein the target comprises a first pattern layer and a second pattern layer under the first pattern layer,
pitch values of the first pattern layer and the second pattern layer are equal to a pitch value of the target, and
the first pattern layer has no predetermined shift relative to the second pattern layer.
42. The computer-implemented method of clause 41, wherein each of the first pattern layer and the second pattern layer comprises a grating.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A system, comprising:
a charged-particle beam inspection apparatus configured to scan a sample; and
a controller including circuitry, configured to:
obtain a first detector signal in response to a first scan of a first target of the sample and a second detector signal in response to a second scan of a second target of the sample;
determine a first transformed signal and a second transformed signal by performing a Fourier transform on the first detector signal and the second detector signal; and
determine, based on the first transformed signal and the second transformed signal, an overlay value of the sample.

2. The system of claim 1, wherein a first period of the first transformed signal corresponds to a first pitch value of the first target, and a second period of the second transformed signal corresponds to a second pitch value of the second target.

3. The system of claim 1, wherein the charged-particle beam inspection apparatus comprises a scanning electron microscope, and the sample comprises a wafer.

4. The system of claim 1, wherein the first target comprises a first pattern layer and a second pattern layer under the first pattern layer,
the second target comprises a third pattern layer and a fourth pattern layer under the third pattern layer,
pitch values of the first pattern layer and the second pattern layer are equal to a first pitch value of the first target, and
pitch values of the third pattern layer and the fourth pattern layer are equal to a second pitch value of the second target.

5. The system of claim 4, wherein each of the first pattern layer, the second pattern layer, the third pattern layer, and the fourth pattern layer comprises a grating.

6. The system of claim 4, wherein the first pattern layer has a first shift relative to the second pattern layer, wherein the first shift has a magnitude equal to the overlay value minus a predetermined shift value,
the third pattern layer has a second shift relative to the fourth pattern layer, wherein the second shift has a magnitude equal to the overlay value plus the predetermined shift value.

7. The system of claim 4, wherein the first pitch value is equal to the second pitch value.

8. The system of claim 7, wherein the controller is further configured to:
determine a first amplitude value of the first transformed signal, a second amplitude value of the second transformed signal, and a third amplitude value associated with a difference between the first transformed signal and the second transformed signal;
determine a phase value representing a partial phase difference between the first transformed signal and the second transformed signal; and
determine the overlay value of the sample based on the phase value and the first pitch value.

9. A non-transitory computer-readable medium that stores a set of instructions that is executable by at least one processor of an apparatus to cause the apparatus to perform a method, the method comprising:
obtaining a first detector signal in response to a first scan of a first target of a sample scanned by a charged-particle beam inspection apparatus and a second detector signal in response to a second scan of a second target of the sample;
determining a first transformed signal and a second transformed signal by performing a Fourier transform on the first detector signal and the second detector signal; and
determining, based on the first transformed signal and the second transformed signal, an overlay value of the sample.

10. The non-transitory computer-readable medium of claim 9, wherein a first period of the first transformed signal corresponds to a first pitch value of the first target, and a second period of the second transformed signal corresponds to a second pitch value of the second target.

11. The non-transitory computer-readable medium of claim 9, wherein the charged-particle beam inspection apparatus comprises a scanning electron microscope, and the sample comprises a wafer.

12. The non-transitory computer-readable medium of claim 9, wherein the first target comprises a first pattern layer and a second pattern layer under the first pattern layer,
the second target comprises a third pattern layer and a fourth pattern layer under the third pattern layer,
pitch values of the first pattern layer and the second pattern layer are equal to a first pitch value of the first target, and
pitch values of the third pattern layer and the fourth pattern layer are equal to a second pitch value of the second target.

13. The non-transitory computer-readable medium of claim 12, wherein each of the first pattern layer, the second pattern layer, the third pattern layer, and the fourth pattern layer comprises a grating.

14. The non-transitory computer-readable medium of claim 12, wherein the first pattern layer has a first shift relative to the second pattern layer, wherein the first shift has a magnitude equal to the overlay value minus a predetermined shift value,
the third pattern layer has a second shift relative to the fourth pattern layer, wherein the second shift has a magnitude equal to the overlay value plus the predetermined shift value.

15. The non-transitory computer-readable medium of claim 12, wherein the first pitch value is equal to the second pitch value.

16. A computer-implemented method of measuring overlay for a sample under a scan performed by a charged-particle beam inspection apparatus, comprising:
obtaining a detector signal in response to a scan of a target of the sample;
determining a first transformed signal by performing a Fourier transform on the detector signal and a second transformed signal by converting the first transformed signal; and
determining an overlay value of the sample based on the first transformed signal, the second transformed signal, a first predetermined amplitude value, and a second predetermined amplitude value.

17. The computer-implemented method of claim 16, wherein the first predetermined amplitude value and the second predetermined amplitude value are associated with two targets adjacent to the target.

18. The computer-implemented method of claim 16, wherein a period of the first transformed signal and a period of the second transformed signal correspond to a pitch value of the target.

19. The computer-implemented method of claim 16, wherein the charged-particle beam inspection apparatus comprises a scanning electron microscope, and the sample comprises a wafer.

20. The computer-implemented method of claim 16, wherein the target comprises a first pattern layer and a second pattern layer under the first pattern layer, pitch values of the first pattern layer and the second pattern layer are equal to a pitch value of the target, and the first pattern layer has no predetermined shift relative to the second pattern layer.
